(19) United States
(12) Patent Application Publication
(10) Pub. No.: US 2025/0233568 A1
(43) Pub. Date: Jul. 17, 2025

(54) JOSEPHSON TRAVELING WAVE PARAMETRIC AMPLIFIER AND METHOD

(71) Applicant: IQM FINLAND OY, Espoo (FI)

(72) Inventor: Aleksei Sharafiev, Espoo (FI)

(21) Appl. No.: 19/016,449

(22) Filed: Jan. 10, 2025

(30) Foreign Application Priority Data
Jan. 12, 2024 (FI) 20245025

(51) Int. Cl. H03F 19/00; H03F 7/00

(52) U.S. Cl. CPC H03F 19/00; H03F 7/00

(57) ABSTRACT

A Josephson traveling wave parametric amplifier (JTWPA) comprising an input for receiving a signal, an output for providing an amplified output of the signal and one or more circuit segments in series between the input and the output and is configured for receiving a pump tone for transferring energy from the pump tone to the signal and to an idler tone. Each of the one or more circuit segments comprises, in series, one or more superconducting nonlinear elements in series, and a first resonator with a first fundamental resonance frequency configured for phase matching the pump tone with the signal and the idler tone and a second resonator with a second fundamental resonance frequency configured for mitigating pump depletion at a frequency corresponding to a higher harmonic of the pump tone with the second fundamental resonance frequency being higher than the first fundamental resonance frequency.

### CROSS-REFERENCE TO RELATED APPLICATIONS

This application claims the benefit of and priority to Finnish Patent Application No. FI20245025, filed on Jan. 12, 2024, the entire contents of which are incorporated herein by reference.

### FIELD

The present invention relates to Josephson traveling wave parametric amplifiers (JTWPAs).

### BACKGROUND

Traveling wave parametric amplifiers are used in various applications, for example in communication systems, scientific research and microwave engineering, to reach high levels of signal amplification with low noise characteristics. Josephson traveling wave parametric amplifiers are nowadays widely used, for example as part of quantum computing systems, different kinds of detectors and so on. Conventional JTWPAs, however, suffer from the so-called pump depletion problem, associated with undesirable nonlinear processes ongoing in the device. This reduces the gain and the spurious free dynamic range (SFDR) of the JTWPA, while decreasing signal to noise ratio.

The pump depletion problem has been solved in two different ways: adjusting plasma frequency cutoff of nonlinear elements or opening a bandgap in the transmission of the JTWPA by periodically modulating either capacitance or inductance of the elementary cells of the device. The first approach, in practice, requires access to a specific technological process with low critical current density, which is not always available and which might be not compatible with other system. The second approach requires either modulation capacitors, which cause additional losses and therefore deteriorates the noise performance (even if a specific low loss dielectric is used), or, when modulating inductance, such a complicated design that it becomes impractical.

### SUMMARY

An objective is to alleviate the pump depletion problem, in particular while alleviating the problems indicated above.

In accordance with the present disclosure, it has been found that a double resonator structure can be used to address independently first and higher harmonics, such as a second harmonic or a third harmonic, of a pump tone of a JTWPA. A first resonator, or a series of resonators, can be used for phase matching of the pump tone with a signal and an idler tone of the JTWPA. For mitigating the pump depletion problem, a second resonator may be introduced for the JTWPA. The fundamental resonance frequency of the second resonator may be chosen higher than the fundamental resonance frequency of the first resonator, for example close to a frequency that is twice the frequency of the pump tone. This allows the gain of the JTWPA to be increased in comparison to a case where only a single resonator is used. The solution allows low introduced loss, for example with the first and/or the second resonators being planar resonators, which can be routinely made with very little internal losses. The solution can also be straightforwardly applied with limited redesign required for existing JTWPAs. Adding the second resonator has only a limited footprint of additional resonators and the solution can be comparatively easily simulated, for example in full time domain, allowing efficient design of JTWPAs with desired characteristics.

According to a first aspect, a Josephson traveling wave parametric amplifier (JTWPA) is provided. The JTWPA comprises an input for receiving a signal, an output for providing an amplified output of the signal and one or more circuit segments in series between the input and the output. The JTWPA, together with the one or more circuit segments thereof, is configured for receiving a pump tone for transferring energy from the pump tone to the signal and to an idler tone. Each of the one or more circuit segments comprises, in series, one or more superconducting nonlinear elements (SNEs) in series, and a first resonator with a first fundamental resonance frequency configured for phase matching the pump tone with the signal and the idler tone and a second resonator with a second fundamental resonance frequency configured for mitigating pump depletion at a frequency corresponding to a higher harmonic of the pump tone with the second fundamental resonance frequency being higher than the first fundamental resonance frequency.

The pump tone may be introduced into the JTWPA by any of the ways familiar to a person skilled in the art of parametric amplification, or JTWPAs in particular. The first resonator can thus promote transfer of energy from the pump tone to the signal and to the idler tone, in particular by adjusting a phase of a first harmonic (i.e. the fundamental frequency) of the pump tone to phase match with the signal and the idler tone. The transfer of energy from the pump tone to the signal and to the idler tone can take place along the one or more circuit segments, possibly including a plurality of circuit segments of the one or more circuit segments. The first resonator allows providing optimal amplification properties through the phase matching.

As described above, the second resonator allows mitigating the pump depletion problem. The second resonator may be configured for its fundamental resonance frequency (i.e. the second fundamental resonance frequency) to be close to the frequency of the higher harmonic of the pump tone to phase mismatch the higher harmonic of the pump tone and therefore mitigate the process of generation of the higher harmonic of the pump tone along the JTWPA, in particular along the one or more circuit segments and the superconducting nonlinear elements therein. The second resonator can thus mitigate parasitic tones at the JTWPA, in particular ones having frequency corresponding to a multiple of the frequency corresponding to the first harmonic of the pump tone.

In an embodiment, the length of each of the one or more segments is smaller than the coherence length for coherence of the pump tone with the signal and the idler tone. Such a coherence length may be understood in terms of a reference JTWPA (rJTWPA) corresponding the JTWPA as defined above so that when the one or more circuit segments are of length corresponding to the coherence length, the rJTWPA has gain equal to one. In an embodiment, the number of superconducting nonlinear elements, including the one or more superconducting nonlinear elements in series, in each of the one or more segments is equal or smaller than a maximum number of superconducting nonlinear elements in the corresponding segment for which the gain of the JTWPA changes 3 percent or less when a superconducting nonlinear element is either added to or removed from the superconducting nonlinear elements of the corresponding segment of the one or more segments. The total number of the superconducting nonlinear elements may be maintained unchanged.

In an embodiment, the first resonator is a phase-matching resonator (PMR).

In an embodiment, the first resonator and/or the second resonator is a lumped element resonator or a distributed LC resonator.

In an embodiment, the first resonator and/or the second resonator is capacitively coupled to the one or more superconducting nonlinear elements of its corresponding circuit segment of the one or more circuit segments.

In an embodiment, the JTWPA is configured for using a three-wave mixing process or a four-wave mixing process for amplification.

In an embodiment, the one or more superconducting nonlinear elements comprises one or more superconducting nonlinear asymmetric inductive elements (SNAILS) and/or RF superconducting quantum interference devices (SQUIDs).

In an embodiment, the difference of the second fundamental resonance frequency and the frequency corresponding to the higher harmonic of the pump tone is less than three times the linewidth of the second resonator.

In an embodiment, the higher harmonic of the pump tone is a second harmonic of the pump tone or a third harmonic of the pump tone. In particular, when the JTWPA is configured for using a three-wave mixing process for amplification the higher harmonic of the pump tone may be the second harmonic of the pump tone. Accordingly, when the JTWPA is configured for using a four-wave mixing process for amplification the higher harmonic of the pump tone may be the third harmonic of the pump tone.

According to a second aspect, a method for a JTWPA, such as the JTWPA according to the first aspect, is disclosed. The method comprises receiving a signal at the JTWPA and amplifying the signal at the JTWPA with one or more circuit segments in series. Each of the one or more circuit segments comprises one or more superconducting nonlinear elements in series, a first resonator and a second resonator. The signal is amplified by receiving a pump tone for transferring energy from the pump tone to the signal and to an idler tone, phase matching the pump tone with the signal and the idler tone in each of the one or more circuit segments by the first resonator with a first fundamental resonance frequency, and mitigating pump depletion at a frequency corresponding to a higher harmonic of the pump tone in each of the one or more circuit segments by the second resonator with a second fundamental resonance frequency, the second fundamental resonance frequency being higher than the first fundamental resonance frequency. Finally, the method comprises providing an amplified output of the signal from the JTWPA.

It is to be understood that the aspects and embodiments described above may be used in any combination with each other. Several of the aspects and embodiments may be combined together to form a further embodiment. The features and effects disclosed in conjunction with either of the first and the second aspect and their embodiments, may be applied correspondingly in conjunction with the other.

### BRIEF DESCRIPTION OF THE DRAWINGS

The accompanying drawings, which are included to provide a further understanding and constitute a part of this specification, illustrate examples and together with the description help to explain the principles of the disclosure. In the drawings:

FIG. 1 illustrates a JTWPA according to an example,

FIG. 2 illustrates a JTWPA according to another example, and

FIG. 3 illustrates a method according to examples.

Like references are used to designate equivalent or at least functionally equivalent parts in the accompanying drawings.

### DETAILED DESCRIPTION

The detailed description provided below in connection with the appended drawings is intended as a description of examples and is not intended to represent the only forms in which the example may be constructed or utilized. However, the same or equivalent functions and structures may be accomplished by different examples.

Disclosed is a Josephson traveling wave parametric amplifier (JTWPA). The JTWPA may be arranged to be used for example in a quantum computing circuit. Accordingly, a quantum computing circuit and a quantum computer comprising one or more JTWPA according to any of the examples described are also disclosed. All disclosed solutions may be configured for operation at cryogenic temperatures. This applies to any or all of the components disclosed herein, in particular to the JTWPAs.

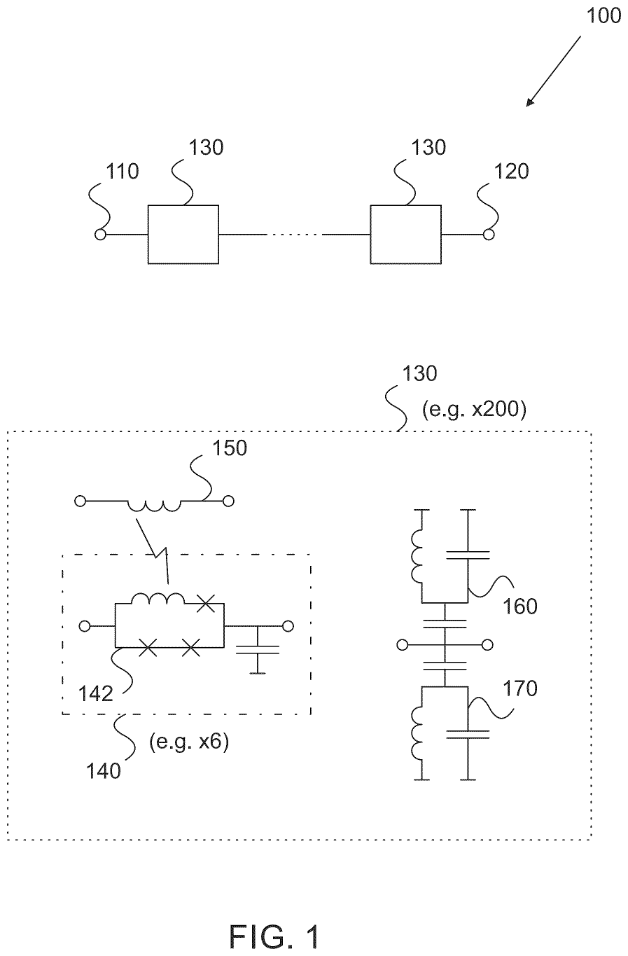

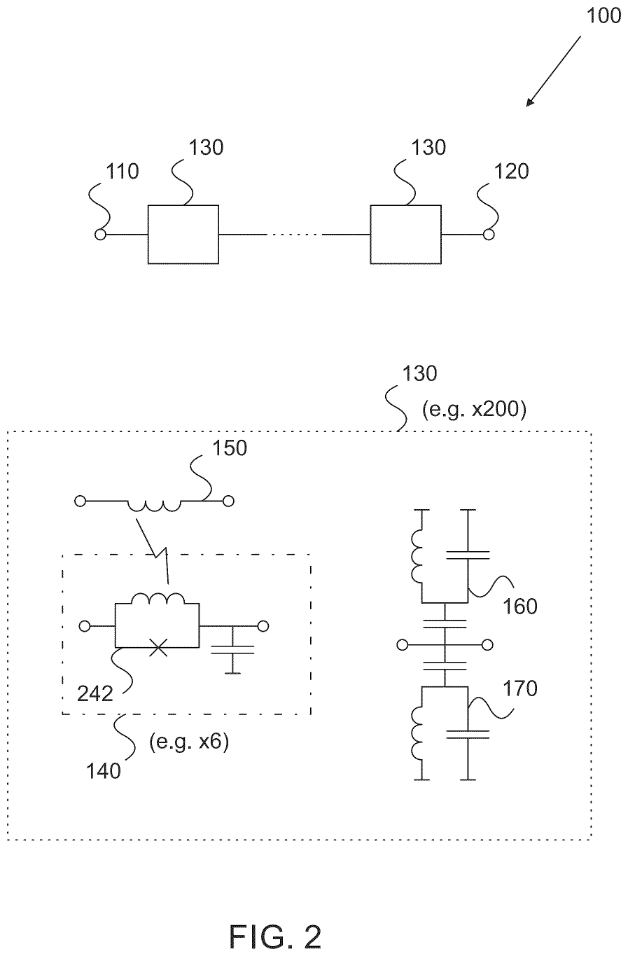

FIGS. 1 and 2 show two examples of a JTWPA 100. The JTWPA comprises an input 110 for receiving a signal and an output 120 for providing an amplified output of the signal. The signal may be a radio frequency (rf) signal. Between the input and the output, the JTWPA comprises one or more circuit segments 130 (herein also “the segments”) in series. The segments are coupled to the input for receiving the signal and to the output for providing the amplified output of the signal. For amplifying the signal, the JTWPA, and the segments, are configured for receiving a pump tone for transferring energy from the pump tone to the signal and to an idler tone. The pump tone can drive parametric amplification for the JTWPA. Any amplification means available to a person skilled in the art of parametric amplifiers, and JTWPAs in particular, can be utilized for this purpose. The pump tone may be a single-frequency continuous wave but other alternatives are also possible.

The number of the segments in series may be more than 100, for example 200 or more. Each of the one or more circuit segments may comprise a non-linear part in series with two or more resonators. The non-linear part may comprise or consist of one or more superconducting nonlinear elements 140 in series. The one or more superconducting nonlinear elements, such as Josephson elements, may comprise or consist of any of the following, alone or in any combination: superconducting nonlinear asymmetric inductive elements (SNAILs) 142 (an example illustrated in FIG. 1), radio-frequency superconducting quantum interference devices (rf SQUIDs) 242 (an example illustrated in FIG. 2), superconducting quantum interference filters (SQIFs) and superconducting junctions with non-linear phase-current characteristics. Such junctions may include superconductor-normal conductor-superconductor (SNS) junctions, superconductor-ferromagnet-superconductor (SFS) junctions and superconductor-insulator-superconductor (SIS) junctions, alone or in any combination. The junctions may have electrically clean interfaces but they may also optionally have electrically insulating interfaces (I), for example so that they include any of SINIS, SINS (i.e. SNIS), SIFIS and SIFS (i.e. SFIS) junctions.

The JTWPA may comprise one or more flux bias lines 150 (herein also “the flux lines”) for magnetically altering the electric current through the superconducting nonlinear element, such as a SNAIL or an rf SQUID. The flux lines may be provided separately for any or each of the superconducting nonlinear elements and/or they may be shared across any or all of the superconducting nonlinear elements. For example, one flux bias line may be shared for all the superconducting nonlinear elements within a single circuit segment of the segments, for any or all of the segments. In particular, one flux bias line may be shared for all the superconducting nonlinear elements across all the segments. The JTWPA may also be configured for the pump tone to be provided by the flux lines. In all the embodiments disclosed, the flux lines may be replaced or supplemented by one or more coils for the same purpose. The one or more coils may be situated outside the chip on which the superconducting nonlinear elements, or the segments, are supported.

The two or more resonators (herein also “the resonators”) comprise a first resonator 160 and a second resonator 170. The resonators may be arranged in parallel, i.e. in electric parallel connection with respect to each other. The resonators each have their own fundamental resonance frequency and for the first resonator this is referred herein as a first fundamental resonance frequency and for the second resonator as a second fundamental resonance frequency. Importantly, the first fundamental resonance frequency may be different from the second fundamental resonance frequency. The first resonator, with its fundamental resonance frequency, may be configured for phase matching the pump tone with the signal and the idler tone. For this purpose, the first fundamental resonance frequency may be close to the frequency corresponding to the first harmonic of the pump tone, e.g. within 10 percent of the frequency corresponding to the first harmonic of the pump tone.

The second resonator, with its fundamental resonance frequency, may be configured for mitigating pump depletion at a frequency corresponding to a higher harmonic, such as the second harmonic or the third harmonic, of the pump tone. For this purpose, the second fundamental resonance frequency may be higher than the first fundamental resonance frequency. The second resonator can prevent or mitigate propagation of the higher harmonic within the JTWPA, or within the segments in particular, by adjusting its phase in a destructive manner. The second fundamental resonance frequency may be close to the frequency corresponding to the higher harmonic of the pump tone, e.g. within 10 percent of the frequency corresponding to the higher harmonic of the pump tone. In an embodiment, the difference of the second fundamental resonance frequency and the frequency corresponding to the higher harmonic of the pump tone may be less than three times the linewidth of the second resonator. Here, the difference may be understood as an absolute value and the second fundamental resonance frequency may be larger or smaller than the frequency corresponding to the higher harmonic of the pump tone. The linewidth may be dependent on the coupling, such as a capacitive coupling, of the second resonator to the segments and/or any losses in the second resonator. As a specific example, the second fundamental resonance frequency may be 20-30 GHZ.

The first and/or the second resonator may be a LC resonator. In an embodiment, the first resonator and/or the second resonator is a lumped element resonator or a distributed LC resonator. The first resonator, in particular, may be a phase-matching resonator (PMR). The first resonator and/or the second resonator may be capacitively coupled to the one or more superconducting nonlinear elements of its corresponding circuit segment of the one or more circuit segments. Each of the first resonator and the second resonator may have a separate capacitive coupling to said one or more superconducting nonlinear elements. The first and the second resonator may be arranged in direct connection, such as a capacitive connection, with each other or they may be separated, for example by any or all of the one or more superconducting nonlinear elements. In general, the first resonator may be arranged for phase matching to promote transfer of energy from the pump tone, and the first harmonic thereof, to the signal. This process may take place along the JTWPA, or along the segments in particular. The first resonator may promote transfer of energy from the pump tone, and the first harmonic thereof, to the idler tone as well. The second resonator may be arranged for phase mismatching for mitigating transfer of energy from the pump tone to one or more parasitic tones, for example having frequencies corresponding to the higher harmonic, such as the second or the third harmonic, of the pump tone. In general, the second resonator may mitigate generation of the one or more parasitic tones at the JTWPA, or the segments in particular, for example at a frequency corresponding to the higher harmonic such as the second harmonic or the third harmonic.

In the figures, couplings between various elements have not been illustrated. Connection interfaces for individual elements or groups of elements have been illustrated as circles (o) in the figures and the elements may be connected to each other through these connection interfaces as described herein, for example in series. It should be understood that any elements described herein may be coupled to each other according to the indications provided with any of the possibilities known to a person skilled in the art of electric circuit design.

The length of any or all of the one or more segments may be smaller than the coherence length for coherence of the pump tone with the signal and the idler tone.

The JTWPA 100 may be provided as a three-wave mixer or as a four-wave mixer. Accordingly, it may be configured for using a three-wave mixing process and/or a four-wave mixing process for amplification. When the JTWPA is configured for using a three-wave mixing process for amplification, the higher harmonic of the pump tone may be the second harmonic of the pump tone. When the JTWPA is configured for using a four-wave mixing process for amplification the higher harmonic of the pump tone may be the third harmonic of the pump tone.

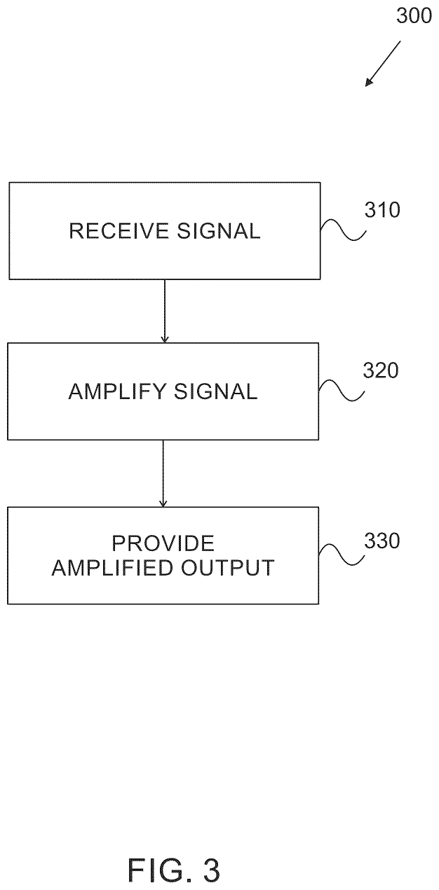

FIG. 3 shows an example of a method 300. The method 300 may comprise any acts discussed in relation to the JTWPA 100. The method may be used for a JTWPA, e.g. as described herein, for example for a quantum computing circuit and/or a quantum computer. The method may be performed at a cryogenic temperature.

The method 300 comprises receiving 310 a signal at the JTWPA and amplifying 320 the signal at the JTWPA. The signal may be amplified using any or all techniques as disclosed herein. The signal may be amplified with one or more circuit segments (such as the segments disclosed above) in series, each of the one or more circuit segments comprising one or more superconducting nonlinear elements in series, a first resonator and a second resonator (such as the resonators described above).

The signal may be amplified by the one or more circuit segments by receiving a pump tone for transferring energy from the pump tone to the signal and to an idler tone and phase matching the pump tone with the signal and the idler tone in each of the one or more circuit segments by the first resonator with a first fundamental resonance frequency. Pump depletion may be mitigated at a frequency corresponding to a higher harmonic of the pump tone in each of the one or more circuit segments by the second resonator with a second fundamental resonance frequency, the second fundamental resonance frequency being higher than the first fundamental resonance frequency.

Finally, the method may comprise providing 330 an amplified output of the signal from the JTWPA.

The different functions discussed herein may be performed in a different order and/or concurrently with each other, unless indicated otherwise.

The expression “in series” may be understood to refer to an electrical series connection.

Any range or device value given herein may be extended or altered without losing the effect sought, unless indicated otherwise. Also any example may be combined with another example unless explicitly disallowed.

Although the subject matter has been de-scribed in language specific to structural features and/or acts, it is to be understood that the subject matter defined in the appended claims is not necessarily limited to the specific features or acts de-scribed above. Rather, the specific features and acts described above are disclosed as examples of implementing the claims and other equivalent features and acts are intended to be within the scope of the claims.

It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item may refer to one or more of those items.

The term ‘comprising’ is used herein to mean including the method, blocks or elements identified, but that such blocks or elements do not comprise an exclusive list and a method or apparatus may contain additional blocks or elements.

Numerical descriptors such as ‘first’, ‘second’, and the like are used in this text simply as a way of differentiating between parts that otherwise have similar names. The numerical descriptors are not to be construed as indicating any particular order, such as an order of preference, manufacture, or occurrence in any particular structure.

Although the invention has been the described in conjunction with a certain type of apparatus and/or method, it should be understood that the invention is not limited to any certain type of apparatus and/or method. While the present inventions have been described in connection with a number of examples, embodiments and implementations, the present inventions are not so limited, but rather cover various modifications, and equivalent arrangements, which fall within the purview of the claims. Although various examples have been described above with a certain degree of particularity, or with reference to one or more individual embodiments, those skilled in the art could make numerous alterations to the disclosed examples without departing from the scope of this specification.

1. A Josephson traveling wave parametric amplifier (JTWPA), comprising an input for receiving a signal, an output for providing an amplified output of the signal and one or more circuit segments in series between the input and the output, configured for receiving a pump tone for transferring energy from the pump tone to the signal and to an idler tone, each of the one or more circuit segments comprising, in series:
one or more superconducting nonlinear elements in series, and
a first resonator with a first fundamental resonance frequency configured for phase matching the pump tone with the signal and the idler tone and a second resonator with a second fundamental resonance frequency configured for mitigating pump depletion at a frequency corresponding to a higher harmonic of the pump tone with the second fundamental resonance frequency being higher than the first fundamental resonance frequency.

2. The JTWPA according to claim 1, wherein the length of each of the one or more segments is smaller than the coherence length for coherence of the pump tone with the signal and the idler tone.

3. The JTWPA according to claim 1, wherein the first resonator is a phase-matching resonator (PMR).

4. The JTWPA according to claim 1, wherein the first resonator and/or the second resonator is a lumped element resonator or a distributed LC resonator.

5. The JTWPA according to claim 1, wherein the first resonator and/or the second resonator is capacitively coupled to the one or more superconducting nonlinear elements of its corresponding circuit segment of the one or more circuit segments.

6. The JTWPA according to claim 1, wherein the JTWPA is configured for using a three-wave mixing process or a four-wave mixing process for amplification.

7. The JTWPA according to claim 1, wherein the one or more superconducting nonlinear elements comprises one or more superconducting nonlinear asymmetric inductive elements (SNAILs) and/or RF superconducting quantum interference devices (SQUIDs).

8. The JTWPA according to claim 1, wherein the difference of the second fundamental resonance frequency and the frequency corresponding to the higher harmonic of the pump tone is less than three times the linewidth of the second resonator.

9. The JTWPA according to claim 1, wherein the higher harmonic of the pump tone is a second harmonic of the pump tone or a third harmonic of the pump tone.

10. A method for a Josephson traveling wave parametric amplifier (JTWPA), comprising:
receiving a signal at the JTWPA,
amplifying the signal at the JTWPA with one or more circuit segments in series, each of the one or more circuit segments comprising one or more superconducting nonlinear elements in series, a first resonator and a second resonator, by:
receiving a pump tone for transferring energy from the pump tone to the signal and to an idler tone,
phase matching the pump tone with the signal and the idler tone in each of the one or more circuit segments by the first resonator with a first fundamental resonance frequency, and
mitigating pump depletion at a frequency corresponding to a higher harmonic of the pump tone in each of the one or more circuit segments by the second resonator with a second fundamental resonance frequency, the second fundamental resonance frequency being higher than the first fundamental resonance frequency; and
providing an amplified output of the signal from the JTWPA.
